(19) United States
(12) Patent Application Publication
(10) Pub. No.: US 2007/0188717 A1
(43) Pub. Date: Aug. 16, 2007

(54) Method for producing crystal elements having strategically oriented faces for enhancing performance

(76) Inventor: Charles L. Melcher, Oak Ridge, TN (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 11/354,063

(22) Filed: Feb. 14, 2006

(51) Int. Cl. G03B 21/26; C30B 15/00; C30B 27/02

(52) U.S. Cl. 353/34; 117/13; 117/26; 117/63

(57) ABSTRACT

A method is provided for producing a plurality of crystal elements having at least one flat face. The method includes providing a crystal boule grown from a seed crystal, said seed crystal having at least one flat face, each of said at least one flat face having a respective surface meeting a respective predetermined etching-related criterion. At least one crystal element is cut from the crystal boule, each crystal element formed by cutting along a plane that is substantially parallel to each respective flat face of the at least one flat face of the seed crystal, each cut forming a flat face that corresponds to and is substantially parallel to one of the at least one flat face of the seed crystal.

### BACKGROUND

The present disclosure relates to a method for forming a scintillator crystal and extracting crystal elements from the scintillator crystal. More particularly, the present disclosure relates to a method for forming a scintillator crystal using a seed crystal having at least one flat face that is selected for an etching-related characteristic of the surface of the at least one flat face, and a method for strategically extracting crystal elements from the scintillator crystal by strategically cutting at least one flat face for each of the crystal elements for enhancing performance of the extracted crystal elements.

### TECHNICAL FIELD

Various types of scintillator crystals, e.g., Lu₂SiO₅, etc., used for radiation detection are typically grown from a melt of raw material which forms on a seed under controlled thermal and chemical conditions. The Czochralski technique for growing crystals is one technique which originates from the pioneering work of Jan Czochralski in 1917 who first managed to successfully pull single crystals of various metals. Since then the Czochralski technique has been used to grow germanium and silicon and has been extended to grow a wide range of compound semiconductors, oxides, metals, and halides. It is considered the dominant technique for the commercial production of most of these materials. Generally, the process involves contacting the surface of the melt with a rotating seed and then pulling the seed upward as molten material nucleates onto the seed to form the single crystal boule.

More particularly, the Czochralski technique typically involves the following steps:
filling a suitable crucible with the raw material, e.g., appropriate quantities of Lu₂O₃, SiO₂, and CeO₂;
melting the raw material in the crucible and keeping its temperature close to the melting point.
lowering a rotating seed crystal to contact the surface of the melt and controlling the temperature of the melt to allow gradual nucleation of material onto the seed crystal;
adjusting the growth rate to grow the commercial part of the boule at, e.g., about one mm/hour at a desired diameter;
adjusting the temperature, pull rate and rotational speed to maintain the homogeneity of the boule until the melt is almost exhausted; and
extracting the boule from the melt once the desired length has been obtained.

Once the scintillator crystal boule is grown, a plurality of crystal elements may be cut from the boule. It is often times desirable to produce smooth surfaces on the crystal elements. One method of smoothing the surfaces of the crystal elements is by mechanical polishing individual surfaces. However, mechanical polishing is slow, labor intensive and inefficient for mass production.

Another method typically used for smoothing the faces of a crystal element is chemical etching, in which the faces of the crystal element are exposed to an etching chemical, such as an acid. In a crystal element cut from a material with a low symmetry crystal structure such as Lu2SiOl, the physical orientation of the various faces may vary with respect to the crystallographic orientation of the crystal element, thus contributing to different etching rates of the various faces, even under substantially similar etching conditions. When the various faces of a crystal element have different etching rates the resultant smoothness of the various faces after etching is not the same, which may lead to undesirable results, as described further below. Furthermore, when etching conditions (e.g., temperature of the acid bath and duration of etching) are optimized for one particular face of a crystal element, a surface having less than optimal characteristics may result on other faces of the crystal element due to the different etching rates of the various faces.

Individual scintillator crystal elements or an array of scintillator crystal elements are used to detect radiation. Upon exposure to radiation the scintillator crystal element absorbs radiation and produces a flash of light, where the intensity of the light corresponds to the energy of the radiation. Circuitry is provided for converting the light pulse into an electrical signal which may be processed by a computing device. The crystal elements may be used to detect whether radiation is present or not, or to provide a visualization of a field that is concealed from view (e.g., internal to a living body, below the ground, below the ocean floor, in a closed container, etc.) that has been exposed to radiation, where the visualization provides information about elements in the field. Applications for scintillator crystal elements include medical imaging (e.g., positron emission technology (PET)), security, geo-physical exploration, power plant monitoring, etc. Detection and proper conversion of the light generated by each crystal element into a signal that corresponds to the intensity of the light generated by the individual crystal elements may be critical in determining the amount of radiation detected and/or for generating an accurate visualization of the concealed field.

It is critical for the light produced by the scintillator crystal elements to be detected and converted into a corresponding electrical signal that has a property (e.g., voltage or current) that corresponds in magnitude to the intensity of the detected light. The light produced by a scintillator crystal element emanates multi-directionally. Accordingly, all but one face of the crystal element is typically coated with a reflective coating, so that substantially all of the light produced in a flash of light exits through the one face that is not coated with the reflective coating.

In order for the circuitry to generate a signal that is truly indicative of the energy of the detected radiation, it is important for the light generated by the crystal elements to be maximally and substantially uniformly reflected from all of the coated surfaces. Accordingly, the coated surfaces should have substantially the same and optimal (e.g., maximal) reflecting properties.

However, when the smoothness of the various faces of a crystal vary, such as due to uneven etching rates for the various faces, even under substantially similar etching conditions, the reflective coating may not be uniformly effective, the variation in smoothness may contribute to different reflecting properties for the various faces, and the reflecting property for at least some of the faces may be non-optimal.

Accordingly, a need exists for a method for producing crystal elements (e.g., scintillator crystal elements), in which the various faces of the individual crystal elements, all etch at a substantially similar rate when etched under substantially similar etching conditions. Furthermore, a need exists for a method for mass producing crystal elements in which the various faces of a crystal element have substantially the same reflecting properties.

### SUMMARY

In one embodiment of the present disclosure, a method is provided for producing a plurality of crystal elements having at least three flat faces. The method includes providing a single crystal boule grown from a seed crystal, said seed crystal having at least three flat faces, each of said at least three flat faces having a surface meeting a predetermined etching-related criterion. At least one crystal element is cut from the crystal boule, each crystal element formed by cutting along a plane that is substantially parallel to each respective flat face of the at least three flat faces of the seed crystal, each cut forming a flat face that corresponds to and is substantially parallel to one of the at least three flat faces of the seed crystal.

In another embodiment of the present disclosure, a method is provided for growing a single crystal boule in which at least one plane is identifiable to cut along for cutting a crystal element from the crystal boule, each respective cut corresponding to a flat face of the crystal element, each respective identifiable plane of the at least one identifiable plane having a desired relationship between the orientation of the identifiable plane and a crystallographic orientation of the crystal boule.

The method includes growing one or more single first generation crystal boules with at least one and random crystallographic orientation. A plurality of crystal elements are cut from the first generation crystal boules, where respective crystal elements of the plurality of crystal elements are cut to have a variety of physical orientations relative to their respective crystallographic orientations, each crystal element of the plurality of crystal elements having at least one flat face. It is understood that the crystal elements will have various and random crystallographic orientations. The plurality of crystal elements are etched by providing substantially the same exposure of each flat face of the individual crystal elements of the plurality of crystal elements to an etching agent.

A crystal element is selected from the etched plurality of crystal elements which has at least one flat face, each flat face of the at least one flat face having a respective surface that meets a respective predetermined etching-related criterion. A second generation crystal boule is grown using the selected crystal element as the seed crystal, wherein at least one plane is identifiable to cut along for cutting a crystal element from the second generation crystal boule, each respective plane of the at least one identifiable plane corresponding to a flat face of the at least one flat face of the selected seed crystal and lying in a plane substantially parallel to the plane in which the flat face of the at least one flat face of the selected seed crystal lies.

In yet another embodiment of the present disclosure, an imaging device is provided having an array of crystal elements for detecting radiation and emitting light having intensity proportional to the energy of the radiation detected, and circuitry for converting the light into an electrical signal having a property proportional to the intensity of the light. The individual crystal elements are produced using the method of first growing at least one first generation crystal boule of random crystallographic orientation and cutting a first plurality of crystal elements from the first generation crystal boules, where respective crystal elements of the first plurality of crystal elements are cut to have a variety of physical orientations relative to their respective crystallographic orientations, each crystal element of the first plurality of crystal elements having at least one flat surface. The first plurality of crystal elements is etched by providing substantially the same exposure of each flat face of the individual crystal elements of the first plurality of crystal elements to an etching agent.

A crystal element is selected from the etched first plurality of crystal elements which has at least one flat face, each flat face of the at least one flat face having a respective surface that meets a predetermined etching-related criterion. A second generation single crystal boule is grown using the selected crystal element as the seed crystal. A second plurality of crystal elements is cut from the second scintillator crystal, wherein each crystal element is formed by cutting along a plane that is substantially parallel to each respective flat face of the at least one flat face of the selected seed crystal, each cut forming a flat face that corresponds to and is substantially parallel to one of the at least one flat face of the selected seed crystal.

### BRIEF DESCRIPTION OF THE DRAWINGS

Various embodiments of the subject apparatus are described herein with reference to the drawings wherein:

FIG. 1 is a schematic, cross sectional side view of a second generation crystal boule produced from a selected seed crystal in accordance with the present disclosure;

FIG. 2 is a schematic cross sectional top view of the second generation crystal boule shown in FIG. 1; and

FIG. 3 is a perspective view of a selected seed crystal in accordance with the present disclosure.

### DETAILED DESCRIPTION

A method is provided for producing a high yield of crystal elements (e.g., cut from a scintillator crystal boule or other type of crystal boule) in which the crystallographic orientation of the crystal boule is controlled. The crystal boule is strategically cut in order to produce crystal elements whose faces meet one or more predetermined etching-related criteria for enhancing the performance of the crystal elements. More particularly, the crystal elements produced in accordance with the present disclosure each have side faces that etch at a predictable and even rate. Where desired, each of the side faces etches at substantially the same rate. Once etched, the surfaces of the respective side faces have substantially the same and smoothness, e.g., reflectivity properties, where the smoothness is optimal.

The faces of the crystal elements are smoothed using a method that is conducive to mass production, such as the method of chemical etching. A preferred crystallographic orientation of the crystal boule is achieved, controlled and reproduced with high precision using a simple mechanical process that is compatible with mass production processes. The crystal elements are cut in a strategic fashion so that a relationship between the crystallographic orientation of the crystal boule from which they are cut and the orientation of the cut is achieved, where the relationship correlates with meeting the desired etching-related criteria and achieving an optimal surface finish on the crystal elements' side faces once the crystal elements are etched. Where desired, substantially the same quality surface finish is achieved for all of the side faces of each of the crystal elements.

The resultant crystal elements advantageously exhibit enhanced performance in reflecting and directing light in a selected direction. A device using the resultant crystal elements will benefit from enhanced performance including improved light collection, energy resolution, processing performance and resultant image generation. Additionally, the process of producing the crystal elements in accordance with the present disclosure improves the yield and lowers the cost of the high performance crystal elements.

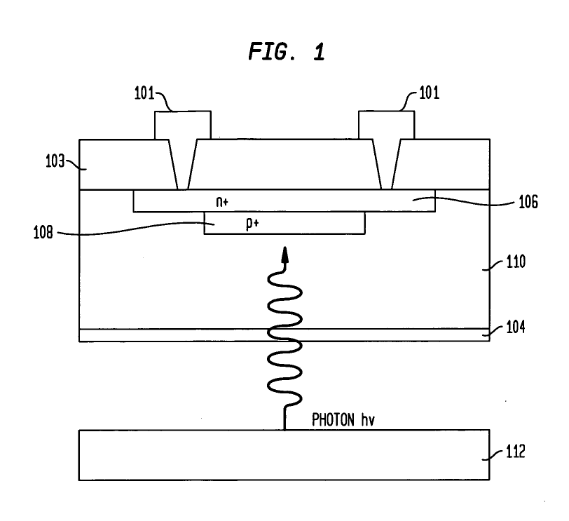

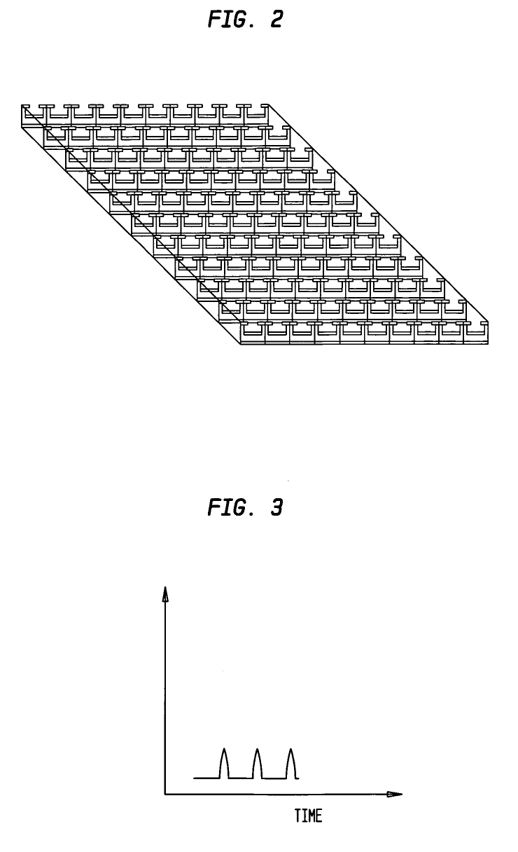

The method of the present disclosure is described with reference to FIGS. 1 and 2. A second generation crystal boule 12 is grown from a selected seed crystal 14 having at least one flat side face 16 that is oriented substantially vertically. It is contemplated that the at least one flat side face 16 may be slanted with respect to the vertical. Each of the at least one flat face 16 has a surface that meets a predetermined etching-related criterion. The etching-related criterion relates to the qualities of the surface that determine the degree of smoothness and/or reflectivity of the flat face 16 after it is etched under predetermined etching conditions, or the degree of smoothness and/or reflectivity of the flat face 16 that is predicted were the selected seed crystal 14 to be etched under predetermined etching conditions.

In the example shown in FIGS. 1 and 2, the selected seed crystal 14 has a rectangular cross-section and four flat side faces 16 that meet a predetermined etching-related criterion. Accordingly, all four flat side faces 16 are etched or will be etched), by achieving substantially the same etching rate for the four flat faces 16, and the surface of the flat faces 16, once etched have substantially the same smoothness, where the smoothness is maximized.

The selected seed crystal 14 is obtained by first growing one or more first generation crystal boules (not shown), each crystal boule grown using a respective seed crystal, wherein at least one of a crystallographic orientation and a physical orientation of the original seed crystal is random or a relationship there between is random. The physical orientation may be, for example, the orientation of a longitudinal axis of the original seed crystal, or the orientation of a plane within which a face of the original seed crystal lies, with respect to a reference axis.

At least one batch of crystal elements is cut from the one or more first generation crystal boules, each crystal element of the at least one batch of crystal elements having four flat side faces. The cutting is performed so that the crystal elements have a variety of physical orientations relative to their respective crystallographic orientations. It is understood that the crystal elements have various and random crystallographic orientations. In the present example, the crystal elements of the at least one batch of crystal elements each have side faces that are substantially parallel to a longitudinal axis the crystal element. The crystal elements are cut to have four flat side faces that are configured with a configuration desired for the seed crystal to be selected, and ultimately with a configuration desired for the crystal elements to be produced from a crystal grown using the selected seed crystal. The respective crystal elements are cut with a variety of physical orientation, so that a large variety of crystal elements are produced, each having different relationships between their physical orientation and their crystallographic orientations.

Once cut, the crystal elements of the at least one batch of crystal elements are etched by providing a substantially the same exposure for all of the faces of the individual crystal elements to be etched to an etching agent. Providing the same exposure for two or more faces includes, for example, using substantially the same etching agent for each face, exposing each face to the etching agent for a substantially similar amount of time, and exposing each face to the etching agent under substantially similar atmospheric (temperature, humidity, air pressure, etc.) conditions.

After the at least one batch of crystal elements is cut and etched, the surfaces of the faces of the crystal elements of the at least one batch of crystal elements are observed. Since no consideration was given as to the crystallographic orientation of the crystal boules(s) from which the at least one batch of crystal elements was cut, and the respective crystal elements were cut at a variety of physical orientations, various faces of each of the cut crystal elements exhibit different degrees of smoothness and light reflectivity after etching, even when etched under substantially similar etching conditions. Some of the faces of some of the cut crystals elements may have surfaces which are optimally smooth. A crystal element is selected from the etched at least one batch of crystal elements that has a desired surface quality on the four flat side faces (also referred to as a flat face or face), e.g., maximized smoothness, where the smoothness of each of the surfaces of the respective four flat sides is substantially the same. The selected crystal element is used as the selected seed crystal 14. Selection is made by evaluating the smoothness and/or reflectivity of the surfaces of the faces of the etched crystal elements.

In other examples, the crystal elements cut from the first generation of boules may have a cross-section that is shaped as a polygon other than a rectangle, and the individual crystal elements may have, for example, three, five or six (or more) flat faces. The faces all of the selected crystal element meet a predetermined etching-related criterion, and would etch or were etched, with substantially the same etching rate for each of the flat faces. The surfaces of the respective flat faces, once etched have substantially the same smoothness, where the smoothness is maximized

In still another example, the crystal elements cut from the first generation crystal boules may have at least one flat face. Each of the at least flat faces of the selected crystal element may meet a respective predetermined etching-related criterion, where the etching-related criterion is different for the respective faces. Using the same etching conditions for etching all of the faces of the at least one flat face, the faces may etch at different respective rates, where it is desired to reproduce the selected seed crystal 14 for achieving the different etching rates in other crystals.

In other examples, it is possible for the selected seed crystal 14 (as well as the crystal elements from the at least one batch of crystal elements) to have a combination of one or more flat faces and one or more faces which are not flat, where the etching behavior of some or all of the flat faces is of interest. It may be desired for all of the flat faces of interest to have substantially the same etching behavior (and therefore smoothness quality and reflective property), or it may be desired for some of the flat faces of interest to have different etching behaviors. The smoothness criterion is not limited to a high degree of smoothness or reflectivity, but may refer to a lesser degree of smoothness or reflectivity.

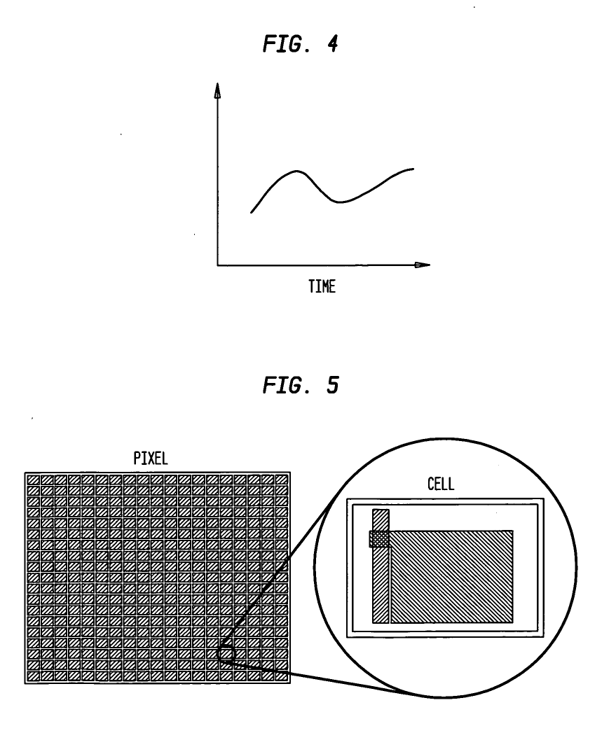

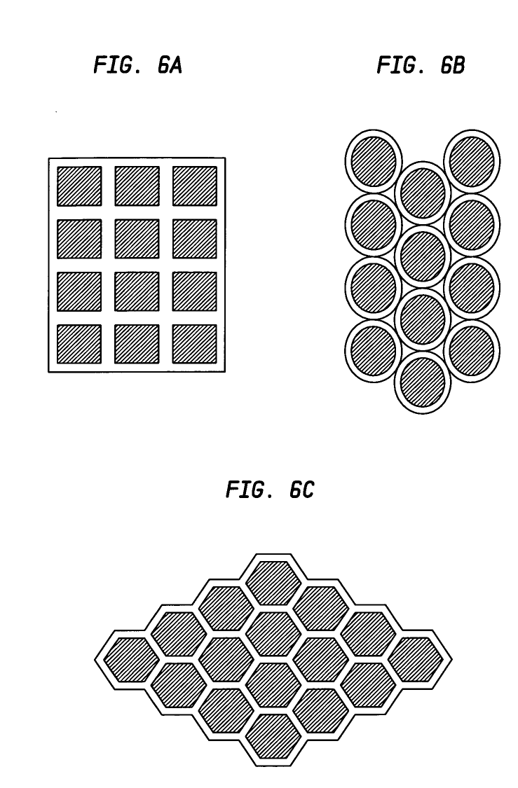

A perspective view of an exemplary selected seed crystal 14 is shown in FIG. 3. The crystal elements of the at least one batch of crystal elements may be cut to have a substantially similar shape, however one of the crystal elements is selected to be the selected seed crystal 14 due to the etching behavior of the surfaces of its faces. In the example provided, the seed crystal 14, like the other crystal elements cut from the first generation crystal boules, has four flat side faces A, B, C and D running substantially parallel with a longitudinal axis 24, and further has a rectangular transverse cross-section. The selected seed crystal 14 further has a top and bottom face, E and F, respectively, where the shape or quality of the surface of top and bottom faces is not limited to any particular shape or quality.

Seed crystal 14 was selected after etching in accordance with the smoothness quality (which is related to the etching behavior) of the surfaces of flat faces A, B, C and D. It is noteworthy that the reflectivity of a face is further related to the smoothness quality of the face. In the example provided, it is desired for the flat surfaces A-D, respectively, to have substantially the same smoothness qualities and reflective properties, to be very smooth and to have a high reflective property.

The smoothness quality of the flat faces A-D of the selected seed crystal 14 may be evaluated quantitatively. However, in accordance with an embodiment of the present disclosure a visual inspection and qualitative determination of the smoothness quality is adequate. The smoothness quality of a flat face is related to the etching behavior of the flat face which correlates with a relationship (e.g., ratio or difference) between a physical orientation of the flat face, which is the orientation of the flat face with respect to a reference axis, and the crystallographic orientation of the selected crystal element.

Quantitative determination of the crystallographic orientation of a crystal may be performed using methods that are known in the art, such as the Laue X-ray back reflection method. However, such quantitative determinations are time consuming and not conducive to mass production. Additionally, the physical orientation of the flat faces may be determined quantitatively. As mentioned above, in the present example, it is not necessary to make a determination of the crystallographic orientation of the crystal elements and the physical orientation of the flat faces of the crystal elements for selecting the seed crystal. The selected seed crystal 14 is selected by a qualitative analysis via visual inspection. However, once selected, it may be useful to determine the selected seed crystal's 14 crystallographic orientation and orientation of its flat faces A-D, such as for baseline measurements which may be used for comparing to in the future, as subsequent generations of crystals are grown.

In other examples, the transverse cross-section of the selected seed crystal 14 may be a polygon such as a rectangle (as shown in FIGS. 2 and 3, a square, a triangle, a diamond, a parallelogram, a pentagon, a hexagon, etc. In general, the transverse cross-section of the selected seed crystal 14 is a shape that is repeatable when positioned side-by-side in a confined space, and could be repeated by way of cutting crystal elements 18 from crystal boule 12 to have a shape substantially similar to the shape of the seed crystal 14, preferably by generating a minimal amount of scrap material from the crystal boule 12.

Growing the second generation crystal boule 12 may be performed in accordance with any method, such as the Czochralski technique, in which a seed crystal is used to grow a single crystal boule of the same crystallographic orientation as the seed crystal. In the Czochralski technique, the crucible is provided with a melt of a raw crystal material. The crucible is heated for keeping the temperature of the melt within the crucible at or close to the melting point of the particular material. The selected seed crystal 14 is held by a seed holder (not shown). The selected seed crystal 14 is introduced into the melt and pulled from the melt as it is rotated. Factors such as the rate at which the selected seed crystal 14 is pulled, the rate at which the selected seed crystal 14 is rotated and the temperature of the melt are controlled for growing the crystal boule 12 as desired. It is understood that other techniques, including the Bridgman technique, may also be used as long as a seed crystal is used to produce a crystal boule of the same orientation as the seed.

The crystal boule 12 grown from the selected seed crystal 14 has a substantially similar crystallographic orientation as the selected crystal seed 14. At least one crystal element 18 is cut from the grown crystal boule 12 so that a longitudinal axis 26 (shown as a dotted line) of the cut crystal elements 18 is substantially parallel with the longitudinal axis 24 of the selected seed crystal 14. Vertical cut lines 20 (shown as dotted lines) indicate the positions in which cuts are to be made to the crystal boule 12 for cutting of the crystal elements 18. The vertical cut lines 20 are physically oriented to be aligned with the side flat faces of the selected seed crystal 14 A-D so that the vertical cut lines 20 each lay in a plane that is substantially parallel to a plane in which one of the flat side faces A-D lays. When the selected seed crystal 14 is held by the seed holder so that each of the side faces whose etching rate is of interest is substantially parallel with a substantially vertical line, the crystal elements 18 are cut by cutting in a plane that is substantially parallel with the substantially vertical line.

The crystal elements 18 may be cut from the crystal boule 12 to have a cross-section that is substantially similar to the cross-section of the seed crystal 14. The crystal elements 18 may have a different size or different proportions than the selected seed crystal 14, however each respective side face of the respective crystal elements 18 whose etching behavior is of interest must be substantially parallel to a corresponding side flat face A-D of the selected seed crystal 14. Furthermore, each of the crystal elements 18 has a substantially similar crystallographic orientation as the crystal boule 12, and therefore as the selected seed crystal 14.

Accordingly, for each of the side faces whose etching behavior is of interest of an individual crystal element 18, the relationship (e.g., ratio or difference) between the orientation of each of the respective side faces of the crystal element 18 and the crystallographic orientation of the crystal element 18 is substantially similar to a relationship between the orientation of the corresponding side face A-D of the selected seed crystal 14 and the crystallographic orientation of the selected seed crystal 14.

It follows that each of the respective side faces meets the etching-related criterion of having an etching behavior that is substantially similar to that of the corresponding side face A-D of the selected seed crystal 14. Additionally, for each of the respective crystal elements 18 and the selected seed crystal 14 that were to be etched under substantially similar etching conditions, each of the respective side faces of the crystal element 18 would meet the smoothness criterion of having a substantially similar smoothness quality and/or reflection property as the corresponding side face A-D of the selected crystal 14.

In the present example, the etching behavior (or potential etching behavior) for all side faces A-D of the selected seed crystal 14 is substantially the same and optimal for producing an optimally smooth surface, e.g., which has a high reflective property. In other examples, a different etching behavior may be desired for different side faces A-D, and/or the desired etching behavior may produce a smoothness quality that includes a higher degree of roughness, e.g., which may have a lower reflective property.

By cutting the crystal elements 18 into repeatable shapes, a high yield of crystal elements 18 may be obtained from crystal boule 12. Cuts may be made along substantially horizontal cut lines 22 (shown as dotted lines) for producing several rows of crystal elements 18. The crystal elements 18 typically do not need to be cut to be as long as the selected seed crystal 14, since a seed crystal is typically elongated in order to make it easier for the seed holder to hold the seed crystal. The amount of crystal material that is not usable for yielding a full-sized crystal element 18 and is scrapped may be minimized by selection of the shape of the selected seed crystal 14 and crystal elements 18. Examples of shapes into which the crystal elements 18 may be cut include diamonds, triangles, pentagons, hexagons, etc. It is also possible that only one crystal element 18 be cut from the crystal boule 12.

Once the crystal elements 18 have been cut, one of the crystal elements 18 may be used as a selected seed crystal 14 for growing another crystal boule 12, from which a new yield of crystal elements 18 may be obtained. It may be desirable to cut some crystal elements 18 with an extended length to be used for future seed crystals, as the additional length may make it easier to mount the seed crystal in the seed holder. When a crystal element 18 from a second generation or later crystal boule is used as the selected seed crystal 14 it is not necessary to etch it and select it. The crystal element 18 already has met the criteria to be selected as the seed crystal 14 due to the way that it was grown and cut. Over numerous cycles of growing crystal elements 18 from an ancestor selected seed crystal 14 (e.g., the originally selected seed crystal 14) in which multiple generations of crystal elements 18 are produced, it is possible for the precise orientation of the faces of subsequent generations of crystal elements 18 to deviate slightly from the original optimal orientation, e.g., substantially parallel to the respective corresponding face of the original selected seed crystal 14.

Accordingly, it may be prudent to perform a baseline test, such as by using a quantitative crystal study, e.g., using the Laue X-ray back reflection method, to determine the crystallographic orientation of the original or an early generation seed crystal (or crystal element). Seed crystals or crystal elements of subsequent generations may be similarly tested occasionally, and the results may be compared to the baseline or previous test results. The results of the comparison may indicate that the desired and optimal etching characteristics will not be obtained for subsequent generations, even before the less than optimal results are visually discernable. Accordingly, an adjustment to the alignment of the seed crystal as held by the seed holder, and/or cutting of the crystal elements may be made, or a new seed crystal may be selected from an unrelated batch of crystal elements.

Table 1 below shows data from measurements taken for a number of different crystal boules grown from different seeds. The boules are numbered 1-19. The crystallographic orientation for the seed crystal used to grow each crystal boule is shown in hkl (Miller indices) notation. The crystallographic orientation of a crystal element cut from each boule was measured, where the crystal element used for the measurement was taken from a same predetermined middle column of each boule. For each boule, the difference between the crystallographic orientation of the seed crystal and the sample crystal element is recorded. The difference in orientation ranges between 1.1° and 7.1°, with more than two-thirds of the difference in orientation results below 3.2°. The small differences between seed and boule orientation are insignificant for many applications, and are due to a less than vertical alignment of the longitudinal axis of the seed crystal while held during growing of the crystal due to the typically loose holding of the seed crystal by the seed holder. By adjusting the grasp of the seed holder on the seed crystal it is believed that the difference in orientation between the seed and the boule may be significantly reduced.

TABLE 1

| Boule | seed orientation | boule orientation |
|---|---|---|
| Designation | [hkl] | with respect to seed |
| 1 | [4 3̅ 2̅] | 2.4° |
| 2 | [4 3̅ 2̅] | 3.9° |
| 3 | [4 3̅ 2̅] | 3.1° |
| 4 | [4 3̅ 2̅] | 4.1° |
| 5 | [4 3̅ 2̅] | 3.7° |
| 6 | [4 3̅ 2̅] | 3.1° |
| 7 | [ 4̅ 3 2] | 3.5° |
| 8 | [ 4̅ 3 2] | 3.1° |
| 9 | [ 4̅ 3 2] | 7.1° |
| 10 | [ 4̅ 3 2] | 2.8° |
| 11 | [4 3̅ 2̅] | 1.2° |
| 12 | [ 4̅ 3 2] | 2.4° |
| 13 | [ 4̅ 3 2] | 1.0° |
| 14 | [0 1 0] | 3.3° |
| 15 | [0 1 0] | 2.5° |
| 16 | [0 1 0] | 1.1° |
| 17 | [1 0 0] | 2.5° |
| 18 | [0 1 0] | 3.1° |
| 19 | [0 0 1] | 1.2° |

From the foregoing and with reference to the various figure drawings, those skilled in the art will appreciate that certain modifications can also be made to the present disclosure without departing from the scope of the same. While several embodiments of the disclosure have been shown in the drawings, it is not intended that the disclosure be limited thereto, as it is intended that the disclosure be as broad in scope as the art will allow and that the specification be read likewise. Therefore, the above description should not be construed as limiting, but merely as exemplifications of preferred embodiments. Those skilled in the art will envision other modifications within the scope and spirit of the claims appended hereto.

What is claimed is:

1. A method for producing a plurality of crystal elements having at least one flat face, the method comprising:
providing a crystal boule grown from a seed crystal, said seed crystal having at least one flat face, each of said at least three flat faces, each of the at least three faces having a surface meeting a predetermined etching-related criterion; and
cutting at least one crystal element from the crystal boule, each crystal element formed by cutting along a plane that is substantially parallel to each respective flat face of the at least three flat faces of the seed crystal, each cut forming a flat face that corresponds to and is substantially parallel to one of the at least three flat faces of the seed crystal.

2. The method according to claim 1, wherein for each of said at least three flat faces, meeting the respective predetermined etching-related criterion correlates with a relationship between a physical orientation of the flat face and a crystallographic orientation of the seed crystal.

3. The method according to claim 1, further comprising exposing a cut crystal element of the at least one cut crystal element to an etching chemical, wherein each flat face that corresponds to a one of the at least three flat faces of the seed crystal are etched at substantially the same rate.

4. The method according to claim 1, wherein the seed crystal at least one of is formed of Lu₂SiO₅ and has a rectangular cross section.

5. The method according to claim 1, wherein the predetermined etching-related criteria provide for maximal reflectivity of the respective surfaces of the at least three faces when the seed crystal is etched.

6. The method according to claim 1, wherein one of the crystal elements of the at least one crystal element is used as a seed crystal for growing a new crystal, and the cutting step is repeated using the new crystal.

7. A method for growing a crystal boule in which at least one plane is identifiable to cut along for cutting a crystal element from the crystal boule, each respective cut corresponding to a flat face of the crystal element, each respective identifiable plane of the at least one identifiable plane having a desired relationship between the orientation of the identifiable plane and a crystallographic orientation of the crystal boule, the method comprising:
growing at least one first crystal boule having a random crystallographic orientation;
cutting a plurality of crystal elements from the at least one first crystal, where respective crystal elements of the plurality of crystal elements are cut to have a variety of physical orientations relative to their respective crystallographic orientations, each crystal element of the plurality of crystal elements having at least one flat face;
etching the plurality of crystal elements by providing substantially the same exposure for each flat face of the individual crystal elements of the plurality of crystal elements to an etching agent;
selecting a crystal element from the etched plurality of crystal elements which has at least one flat face, each flat face of the at least one flat face having a respective surface that meets a respective predetermined etching-related criterion; and
growing a second crystal boule using the selected crystal element as the seed crystal, wherein at least one plane is identifiable to cut along for cutting a crystal element from the second crystal boule, each respective plane of the at least one identifiable plane corresponding to a flat face of the at least one flat face of the selected seed crystal and lying in a plane substantially parallel to the plane in which the flat face of the at least one flat face of the selected seed crystal lies.

8. The method according to claim 7, wherein for each flat face of the at least one flat face, meeting the respective predetermined etching-related criterion correlates with a relationship between a physical orientation of the flat face and a crystallographic orientation of the selected seed crystal.

9. The method according to claim 7, wherein the seed crystals and the first and second crystal boules are formed of Lu₂SiO₅.

10. The method according to claim 7, wherein the selected seed crystal has a rectangular cross section.

11. The method according to claim 7, wherein the at least one flat face of the selected seed crystal includes at least three flat faces and the respective etching-related criteria associated with the at least three flat faces are substantially the same.

12. The method according to claim 11, wherein the respective etching-related criteria provide for maximal reflectivity of the respective surfaces of the at least one face when the selected seed crystal is etched.

13. The method according to claim 7, wherein the selecting is performed via visual inspection.

14. An imaging device comprising:
an array of crystal elements for detecting radiation and emitting light having intensity proportional to energy of the radiation detected;
circuitry for converting the light into an electrical signal having a property proportional to the intensity of the light, the individual crystal elements produced using the method of:
growing a first scintillator crystal boule having a random crystallographic orientation;
cutting a first plurality of crystal elements from the first scintillator crystal boule, where respective crystal elements of the first plurality of crystal elements are cut to have a variety of physical orientations relative to their respective crystallographic orientations, each crystal element of the first plurality of crystal elements having at least one flat surface;
etching the first plurality of crystal elements by providing substantially the same exposure for each flat face of the individual crystal elements of the first plurality of crystal elements to an etching agent;
selecting a crystal element from the etched first plurality of crystal elements which has at least one flat face, each flat face of the at least one flat face having a respective surface that meets a predetermined etching-related criterion;
growing a second scintillator crystal boule using the selected crystal element as the seed crystal; and
cutting a second plurality of crystal elements from the second scintillator crystal boule, wherein each crystal element is formed by cutting along a plane that is substantially parallel to each respective flat face of the at least one flat face of the selected seed crystal, each cut forming a flat face that corresponds to and is substantially parallel to one of the at least one flat face of the selected seed crystal.

15. The imaging device according to claim 14, wherein for each of said at least one flat face of said selected seed crystal, meeting the respective predetermined etching-related criterion correlates with a relationship between a physical orientation of the flat face of the selected seed crystal and a crystallographic orientation of the selected seed crystal.

16. The imaging device according to claim 14, wherein the at least one flat face of the selected seed crystal includes at least three flat faces.

17. The imaging device according to claim 16, wherein the respective etching-related criteria associated with the at least three flat faces are substantially the same.

18. The imaging device according to claim 14, wherein one of the crystal elements of the second plurality of crystal elements is used as a selected seed crystal for growing a new scintillator crystal, and the cutting step is repeated using the new scintillator crystal.

19. The imaging device according to claim 14, wherein the seed crystal is formed of Lu₂SiO₅.

20. The imaging device according to claim 14, wherein the seed crystal has a rectangular cross section.
